(19) United States
(12) Patent Application Publication
(10) Pub. No.: US 2026/0020197 A1
(43) Pub. Date: Jan. 15, 2026

(54) METHOD AND SYSTEM FOR OPTIMIZING COOLING RESOURCES IN A DATA CENTER BASED ON WORKLOAD PREDICTION

(71) Applicant: ProphetStor Data Services, Inc., Taichung (TW)

(72) Inventors: Wen-Shyen Chen, Taichung City (TW); Ming-Jye Sheu, Saratoga, CA (US); Jonathan Chen, Milpitas, CA (US)

(21) Appl. No.: 18/771,062

(22) Filed: Jul. 12, 2024

(51) Int. Cl. H05K 7/20; G06F 1/20

(52) U.S. Cl. CPC H05K 7/20836; G06F 1/206

(57) ABSTRACT

The present invention provides a method for optimizing cooling resources in a data center based on workload prediction and a system thereof. The method includes the steps of: continuously collecting data in real-time from a plurality of sensors distributed across various sections of the data center; predicting future workload demands and corresponding cooling requirements over time and space in each section of the data center using historical and real-time collected data; determining whether to allocate the predicted workload demand to a section that meets the corresponding cooling requirements or to adjust the cooling resources to achieve the required cooling levels, whichever results in more optimized energy usage; and dynamically adjusting the cooling resources in each section of the data center based on real-time and predicted workload demands over time to minimize energy consumption and operational costs, thereby ensuring optimal cooling without over-provisioning.

### FIELD OF THE INVENTION

The present invention relates to a method and a system for optimizing cooling resources in a data center. More particularly, the present invention relates to a method and a system for dynamically managing and controlling cooling resources (e.g., air conditioners, fans, and liquid cooling systems) in a data center based on workload prediction, ensuring optimal temperature regulation, energy efficiency, reduced operational costs, minimized environmental impact, and enhanced sustainability of the cooling devices.

### BACKGROUND OF THE INVENTION

Data centers, the backbone of modern digital infrastructure, house extensive arrays of servers and IT equipment that generate substantial heat, requiring efficient management to ensure optimal performance, reliability, and longevity. Primary cooling challenges include efficiently dissipating heat from densely packed servers, addressing significant energy consumption, controlling operational costs, minimizing environmental impact from carbon emissions, maintaining equipment reliability to prevent overheating and failures, and adapting to dynamic workloads with flexible cooling strategies in real time. Effective thermal management and cooling optimization are essential for maintaining efficiency and sustainability in data centers, such as GPU-based data centers, meeting the demands of evolving technological advancements.

Several cooling technologies are employed in data centers, each with its own strengths and weaknesses. Air cooling uses chilled air to dissipate server heat but struggles with efficiency in high-density environments and consistent temperature maintenance. Liquid cooling, involving chilled water or other fluids in direct contact with heat-generating components, offers better efficiency but entails higher setup costs, complex maintenance, and leak risks. Evaporative cooling uses water evaporation to cool incoming air, but its effectiveness depends on local climate, water usage, and potential for mineral buildup and corrosion. Hybrid cooling systems combine various methods to improve efficiency and reliability but are more complex and costly to implement and maintain. Free cooling leverages favorable outdoor air conditions to minimize mechanical cooling reliance, though its effectiveness is geographically and seasonally constrained. These traditional methods often lack real-time adaptability to dynamic workloads, leading to inefficiencies and increased costs.

The dynamic nature of data center workloads necessitates real-time adaptive cooling solutions, as static systems can lead to energy waste and increased costs from overprovisioning or overheating and equipment failure from under-provisioning. The IEA's “Electricity 2024: Analysis and Forecast to 2026” report highlights a 2.2% global electricity demand growth in 2023, with a projected annual increase of 3.4% through 2026, driven significantly by data centers, AI, and cryptocurrency sectors. It stresses the need for efficiency improvements and updated regulations, projecting data centers' electricity consumption to exceed 1,000 TWh by 2026. In modern GPU-based data centers, cooling and air conditioning account for 30-40% of total electricity consumption, while operating equipment and servers, especially high-performance GPU servers like NVIDIA H100 and H200, consume 50-70%, with each server using about 10 kW. These figures underscore the critical importance of optimizing cooling strategies to enhance overall energy efficiency.

Despite various advancements in data center cooling technologies, traditional systems still operate on fixed parameters without real-time adaptation to changing workloads, resulting in inefficient energy use and over-provisioning. Early systems included basic feedback loops that adjusted cooling based solely on temperature sensors, while more recent solutions have incorporated power efficiency monitoring to some extent. For example, U.S. Pat. No. 8,346,398 teaches how to provide optimized thermal performance and reduce power consumption in data centers by strategically locating sensor modules, preferably microsystems with MEMS technology, and using a processing circuit to acquire data from the sensors and generate a control law for operating the air conditioning system efficiently. Similarly, U.S. Pat. No. 8,634,963 discloses an apparatus comprising an air conditioning unit for supplying cooled air to a cold portion of a data center, an airflow measurement device for measuring bypass airflow, and a control unit to maintain a predetermined rate of bypass airflow.

Patents and guidelines emphasize adaptive fan speed control, liquid cooling adjustments, and airflow management but fall short of utilizing real-time data and predictive analytics for cooling optimization. Even the latest AI-driven and liquid cooling strategies do not fully integrate real-time workload predictions for dynamic adjustments. For instance, U.S. Pat. No. 10,643,121 teaches how to improve operational efficiency within a data center by modeling data center performance and predicting power usage efficiency. However, these systems rely on simple heuristics and static rules, lacking sophisticated workload prediction and machine learning capabilities.

In contrast, the present invention uniquely leverages predictive analytics and machine learning to forecast workloads, enabling proactive and precise cooling adjustments. By dynamically adapting cooling resources based on real-time and predicted workload demands, it ensures optimal energy efficiency and operational effectiveness, addressing the limitations of prior arts and providing a more integrated, application-aware cooling solution.

Addressing the limitations of current cooling technologies, the present invention aims to leverage advanced technologies like machine learning and AI to dynamically predict workload patterns and adjust cooling resources. This approach optimizes energy usage and enhances overall efficiency by incorporating predictive analytics for workload forecasting, real-time adaptation of cooling resources, seamless integration with workload management tools, and consideration of environmental conditions (such as data center, rack, and server temperatures, weather forecast, etc.). It achieves improved energy efficiency through precise cooling adjustments, cost savings from reduced energy consumption, and enhanced reliability by maintaining optimal thermal conditions. Implementing these dynamic, workload-sensitive cooling solutions enables data centers to markedly enhance efficiency, cost-effectiveness, and sustainability, aligning with the evolving needs of modern digital infrastructure.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims. The following presents a simplified summary of one or more aspects of the present disclosure to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

The present invention aims to enhance data center cooling and air conditioning efficiency through a dynamic, workload-sensitive approach. Unlike traditional reactive methods, the present invention leverages predictive analytics and advanced virtualization techniques to allocate resources according to workload dynamics proactively. The present invention doesn't just use machine learning to react at the server level to cooling data and machine temperatures; it proactively forecasts workload needs and uses virtualization to allocate resources more effectively according to workload dynamics. This approach allows dynamic planning and adjustment of air conditioning and cooling fan speeds and cooling liquid movements, maintaining necessary cooling and air conditioning more efficiently. By focusing on specific areas of the data center, it enhances energy efficiency through multi-layer correlation and causal analysis technology. This provides just-in-time cooling and air conditioning tailored for the next generation of GPU-based data centers.

The present invention enhances data center operations by optimizing energy efficiency, system performance, and cost reduction through dynamic cooling adjustments based on real-time and predictive workload demands. It promotes environmental sustainability and application resilience by utilizing multi-layer correlation and causal analysis for just-in-time resource management. The system integrates seamlessly with existing infrastructure, employs real-time workload monitoring, and uses predictive analytics and machine learning to refine cooling adjustments, ensuring precise resource orchestration and maintaining optimal conditions for data center equipment.

In one aspect, the present invention provides a method for optimizing cooling resources in a data center based on workload prediction which includes the steps of: continuously collecting data in real-time from a plurality of sensors distributed across various sections of the data center; predicting future workload demands and corresponding cooling requirements over time and space in each section of the data center using historical and real-time collected data; determining whether to allocate the predicted workload demand to a section that meets the corresponding cooling requirements or to adjust the cooling resources to achieve the required cooling levels, whichever results in more optimized energy usage; and dynamically adjusting the cooling resources in each section of the data center based on real-time and predicted workload demands over time to minimize energy consumption and operational costs, thereby ensuring optimal cooling without over-provisioning.

Preferably, the data collected from the plurality of sensors include: temperatures, workload demands, humidity, environmental metrics, and system performance.

Preferably, the future workload demands are predicted by performing multi-layer correlation and causal analysis.

Preferably, the cooling resources are adjusted to reduce cooling in sections not operating at full capacity and to enhance cooling in sections predicted to generate heat due to increased workload demands.

Preferably, the cooling resources are adjusted by adjusting cooling parameters of the cooling resources, including fan speeds, liquid cooling rates, and air-conditioning settings.

Preferably, each section of the data center includes at least one rack of servers, each with its own set of cooling resources.

Preferably, the cooling resources comprises air cooling system, liquid cooling system, evaporative cooling system, hybrid cooling system, and free cooling system.

Preferably, the method further includes a step of: allocating the predicted workload demand to a section that meets the corresponding cooling requirements, if it results in more optimized energy usage compared to adjusting the cooling resources to achieve the required cooling levels.

Preferably, the method further includes a step of: building and refining a prediction model for predicting future workload demands and corresponding cooling requirements, and a correlation model between the workload demands and the cooling resources using machine learning.

Preferably, the method further includes a step of: hibernating unused or underutilized servers in the data center and adjusting cooling resources to reduce cooling in sections containing these servers.

In another aspect, the present invention provides a system for optimizing cooling resources in a data center based on workload prediction which includes: a plurality of sensors, distributed across various sections of the data center; a data collecting module, connected to the plurality of sensors, for continuously collecting data in real-time from the plurality of sensors; a prediction module, connected to the data collecting module, for predicting future workload demands and corresponding cooling requirements over time and space in each section of the data center using historical and real-time collected data; a processing module, connected to the prediction module, for determining whether to allocate the predicted workload demand to a section that meets the corresponding cooling requirements or to adjust the cooling resources to achieve the required cooling levels, whichever results in more optimized energy usage; and a dynamic adjustment module, connected to the processing module, for dynamically adjusting the cooling resources in each section of the data center based on real-time and predicted workload demands over time to minimize energy consumption and operational costs, thereby ensuring optimal cooling without over-provisioning.

Preferably, the data collected by the data collecting module from the plurality of sensors include: temperatures, workload demands, humidity, environmental metrics, and system performance.

Preferably, the prediction module predicts the future workload demands by performing multi-layer correlation and causal analysis.

Preferably, the cooling resources are adjusted to reduce cooling in sections not operating at full capacity and to enhance cooling in sections predicted to generate heat due to increased workload demands.

Preferably, the cooling resources are adjusted by adjusting cooling parameters of the cooling resources, including fan speeds, liquid cooling rates, and air-conditioning settings.

Preferably, each section of the data center includes at least one rack of servers, each with its own set of cooling resources.

Preferably, the cooling resources comprises air cooling system, liquid cooling system, evaporative cooling system, hybrid cooling system, and free cooling system.

Preferably, the processing module allocates the predicted workload demand to a section that meets the corresponding cooling requirements, if it results in more optimized energy usage compared to adjusting the cooling resources to achieve the required cooling levels.

Preferably, the prediction module comprises a prediction model for predicting future workload demands and corresponding cooling requirements; and a correlation model for calculating correlations between the workload demands and the cooling resources, both using machine learning techniques that are dynamically refined over time.

Preferably, the processing module sets unused or underutilized servers in the data center to hibernating mode; and the dynamic adjustment module reduces cooling in sections containing these hibernating servers.

### BRIEF DESCRIPTION OF THE DRAWINGS

FIG. 1 is a block diagram illustrating major components of a system for optimizing cooling resources in a data center based on workload prediction according to an embodiment of the present invention.

FIG. 2 is a flowchart illustrating a method for optimizing cooling resources in a data center based on workload prediction according to an embodiment of the present invention.

FIG. 3 is a conceptual overview of the method/system according to an embodiment of the present invention.

FIG. 4 is another conceptual overview of the method according to an embodiment of the present invention.

### DETAILED DESCRIPTION OF THE PREFERRED EMBODIMENTS

The present invention will now be described more specifically with reference to the following embodiments. The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form to avoid obscuring such concepts.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation.

The present invention provides a system and a method for optimizing cooling resources in a data center based on workload prediction. The cooling resources may include, but are not limited to, a variety of systems and methods used in data centers to maintain optimal operating temperatures for their equipment. These resources encompass air conditioning units, such as computer room air conditioners (CRAC) that use refrigerants and computer room air handlers (CRAH) that utilize chilled water from chiller plants. Chillers, which remove heat from a liquid via vapor-compression or absorption refrigeration cycles, and cooling towers, which reject heat to the atmosphere using evaporation, are also included. Direct expansion (DX) units, which cool air with refrigerants without a separate chilled water loop, and in-row cooling units, placed between server racks for localized cooling, are part of the spectrum. Overhead cooling units mounted on ceilings, various forms of liquid cooling like cold plates, immersion cooling, and direct-to-chip cooling, are integral to the cooling strategy. Airflow management techniques such as hot aisle/cold aisle containment, blanking panels, and raised floors with underfloor air distribution improve efficiency. Additionally, free cooling methods that utilize favorable external conditions, adiabatic cooling that pre-cools air via evaporation, and the use of high-efficiency fans and variable speed drives for ventilation all contribute to managing thermal loads and ensuring the reliable operation of IT equipment. It's important to note that the present invention extends beyond these instances and is not limited to the mentioned technologies.

Existing cooling strategies mainly focus on controlling the overall temperature and humidity of the entire data center, which often results in wasted energy, increased costs, and a larger carbon footprint due to the uneven generation of heat throughout the facility. In contrast, the present invention addresses this inefficiency by managing the cooling of the data center in distinct sections rather than as a whole. It dynamically adjusts the cooling parameters of the cooling resources in each section based on predicted workloads, ensuring that the cooling resources are allocated precisely where and when they are needed, thus enhancing efficiency and sustainability.

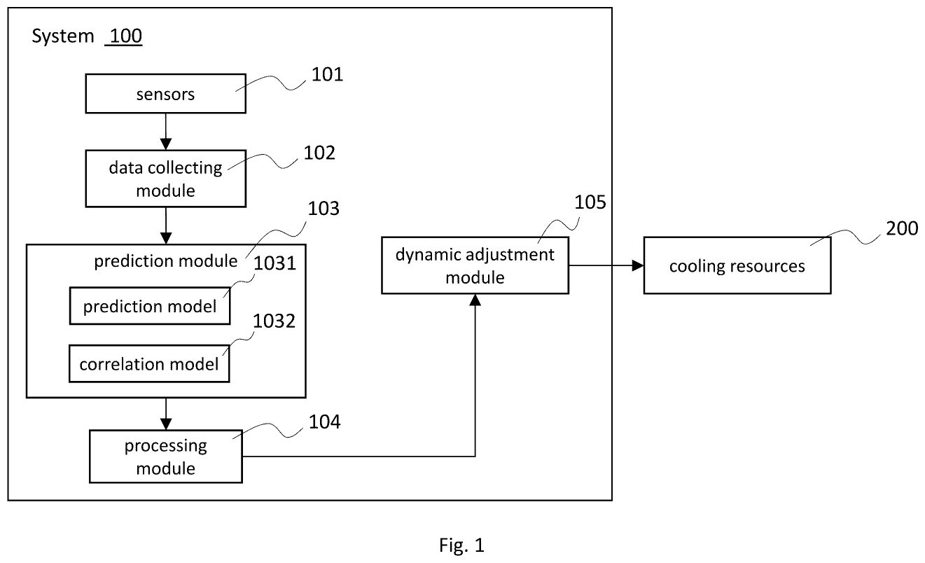

FIG. 1 is a block diagram illustrating major components of a system 100 for optimizing cooling resources 200 in a data center based on workload prediction according to an embodiment of the present invention. The present invention provides a system 100 for optimizing cooling resources 200 in a data center based on workload prediction. The system 100 includes multiple sensors 101 distributed across various sections of the data center. These sensors 101 continuously collect data in real-time, which is then transmitted to a data collecting module 102. The data collecting module 102 is connected to the sensors 101 and is responsible for gathering data such as temperatures, workload demands, humidity, environmental metrics, and system performance.

Connected to the data collecting module 102 is a prediction module 103, which utilizes both historical and real-time data to predict future workload demands and the corresponding cooling requirements over time and space in each section of the data center. The prediction module 103 employs multi-layer correlation and causal analysis for workload predictions. It comprises a prediction model 1031 and a correlation model 1032, both using machine learning techniques that are dynamically refined over time.

The system 100 also includes a processing module 104 connected to the prediction module 103. The processing module 104 determines whether to allocate the predicted workload demand to a section that already meets the cooling requirements or to adjust the cooling resources 200 to achieve the required cooling levels, depending on which option results in more optimized energy usage. The processing module 104 also sets unused or underutilized servers to hibernating mode to further optimize energy usage.

A dynamic adjustment module 105, connected to the processing module 104, is responsible for dynamically adjusting the cooling resources 200 in each section based on real-time and predicted workload demands. The adjustments aim to minimize energy consumption and operational costs while ensuring optimal cooling without over-provisioning. Specifically, the cooling resources 200 can be adjusted to reduce cooling in sections not operating at full capacity and enhance cooling in sections predicted to generate more heat due to increased workload demands. The cooling parameters that can be adjusted include fan speeds, liquid cooling rates, and air-conditioning settings.

Each section of the data center includes at least one rack of servers, each equipped with its own set of cooling resources 200. These cooling resources may include an air cooling system, liquid cooling system, evaporative cooling system, hybrid cooling system, and free cooling system. By utilizing these components, the system 100 efficiently manages the cooling requirements of the data center, ensuring energy-efficient operation and cost savings.

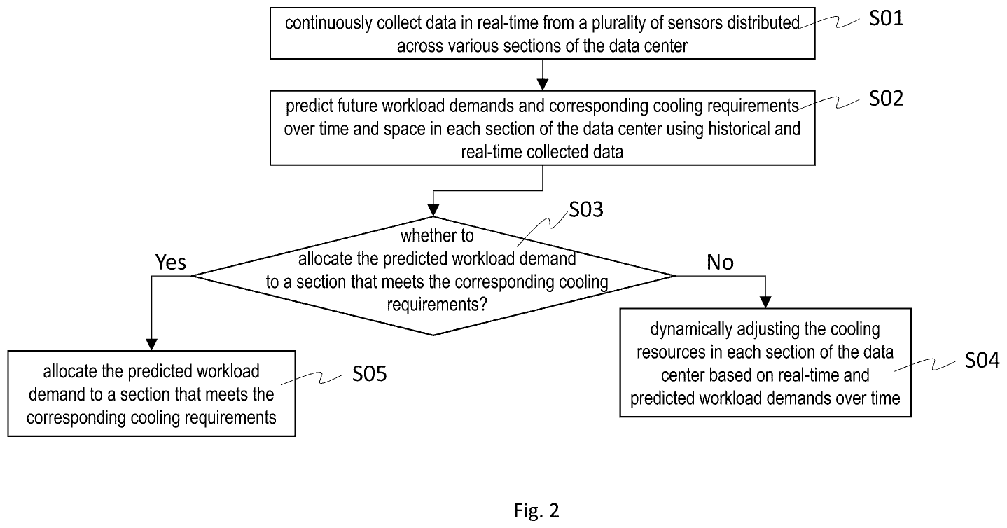

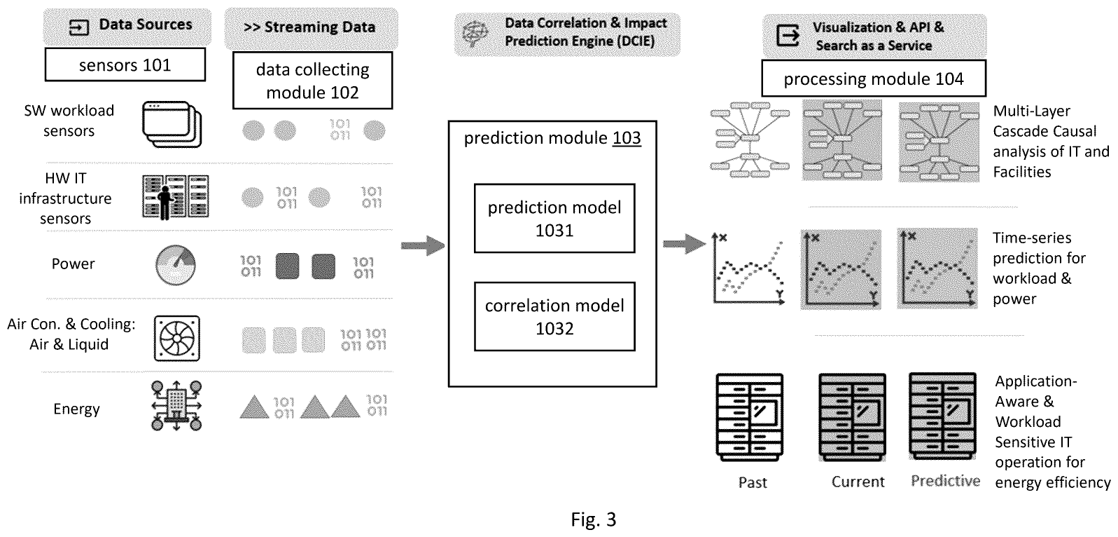

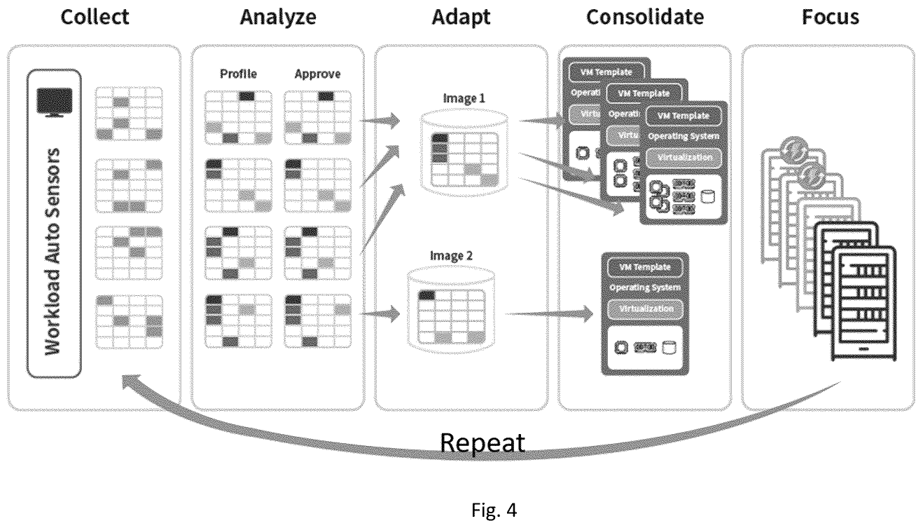

For a better understanding of the present invention, please refer to FIG. 2 which is a flowchart illustrating a method for optimizing cooling resources 200 in a data center based on workload prediction according to an embodiment of the present invention, along with FIGS. 3 and 4 which provide conceptual overviews of the method/system. The method includes several key steps designed to enhance energy efficiency and minimize operational costs while maintaining optimal cooling conditions.

The method begins with the step of continuously collecting data in real-time from multiple sensors 101 distributed across various sections of the data center (step S01). These sensors gather critical information such as temperature, humidity, environmental metrics, and workload demands, which is essential for accurate prediction and efficient management of cooling resources.

In the next step (step S02), the method involves predicting future workload demands and corresponding cooling requirements over time and space in each section of the data center. This prediction is achieved using both historical and real-time collected data. Machine learning techniques are employed to build and refine a prediction model, as well as a correlation model that establishes the relationship between workload demands and cooling resources 200. These models are dynamically refined over time to improve their accuracy and reliability.

Following the prediction phase, the method involves determining whether to allocate the predicted workload demand to a section that already meets the corresponding cooling requirements or to adjust the cooling resources 200 to achieve the necessary cooling levels (step S03). This decision is based on which option results in more optimized energy usage. This step ensures efficient use of cooling resources, either by utilizing sections with sufficient existing cooling or by making the required adjustments to meet the predicted demands.

If it is determined that adjusting the cooling resources 200 to achieve the required cooling levels results in more optimized energy usage, then step S04 is executed. In this step, based on real-time and predicted workload demands, the cooling resources in each section of the data center are adjusted to minimize energy consumption and operational costs. This approach ensures optimal cooling without over-provisioning, thereby enhancing the overall efficiency of the data center.

Conversely, if it is determined that allocating the predicted workload demand to a section that meets the corresponding cooling requirements is more energy-efficient than adjusting the cooling resources 200, then step S05 is executed.

Furthermore, the method may optionally include a step of: hibernating unused or underutilized servers and adjusting cooling resources to reduce cooling in sections containing these servers. This step further contributes to energy savings by minimizing cooling in areas that do not require it, thus aligning cooling efforts with actual demand and enhancing overall system efficiency.

By integrating these steps, the method provides a comprehensive approach to optimizing cooling resources in a data center, leveraging advanced prediction models, real-time data collection, and dynamic adjustments to achieve significant energy savings and cost reductions.

FIGS. 3 and 4 provide conceptual overviews of the method, illustrating the seamless flow of data collection, analysis, and dynamic cooling parameter adjustments. This visualization emphasizes the transition from real-time data collection by workload auto sensors, capturing workload metrics such as temperature and usage patterns, to comprehensive data analysis for profiling and identifying cooling and resource allocation needs. Approved profiles then guide subsequent actions, leading to the creation of dynamic configurations that adapt the cooling system through virtualization templates. The system focuses on specific areas flagged by recommendations of the processing module 104 for cooling adjustments, ensuring optimal energy efficiency and operational conditions. This iterative process forms a feedback loop, continuously adapting to evolving workload demands and enhancing overall cooling effectiveness within data center environments.

In this embodiment, the prediction module 103 employs multi-layer correlation and causal analysis (also known as “Multi-Layer Cascade Causal Analysis”) for workload predictions by utilizing two machine learning models: the prediction model 1031 and the correlation model 1032. This approach is designed to understand and model the causal relationships among variables across multiple layers or levels of a system, where interactions between variables cascade through different layers, resulting in intricate cause-and-effect chains.

The key components and steps involved include the multi-layer structure, correlation analysis, causal analysis, cascade analysis, modeling and prediction, and machine learning integration. The multi-layer structure involves dividing the system into multiple layers, each representing different levels of abstraction or types of data. For instance, in a data center, one layer might represent hardware performance metrics, another could represent software workload characteristics, and another might represent environmental factors like temperature and humidity.

Correlation analysis involves analyzing relationships between variables within each layer to identify potential correlations (within-layer correlation) and examining how variables in one layer correlate with variables in another layer to understand inter-layer dependencies (cross-layer correlation). Causal analysis uses statistical and machine learning techniques to infer causal relationships between variables, which might include methods like Granger causality, structural equation modeling, or Bayesian networks. It also involves identifying and modeling chains of causality that cascade from one layer to another. For example, a change in workload (software layer) might cause a change in CPU temperature (hardware layer), which then affects cooling requirements (environmental layer).

Cascade analysis studies how effects propagate through the layers of the system, understanding not just direct causation but also indirect effects that ripple through the system. It also involves identifying feedback loops where the effects of a change in one layer feed back into itself or other layers, creating complex dynamics. Modeling and prediction involve building models that capture the multi-layer causal relationships and can predict the impact of changes in one part of the system on other parts. These models are used to simulate different scenarios and predict outcomes, aiding in decision-making and optimization.

Machine learning integration employs machine learning algorithms to handle large datasets, uncover hidden patterns, and improve the accuracy of causal inference. Feature engineering is used to create features that capture the multi-layer interactions, enhancing the performance of machine learning models. By incorporating Multi-Layer Cascade Causal Analysis, the prediction module 103 can dynamically adjust cooling parameters based on predicted workloads, optimizing cooling efficiency and energy consumption.

Below is an example of how future workload demands can be predicted via multi-layer correlations. It could be predicted by the following steps: a) deploy and install an application on multiple nodes; b) periodically collect workloads of the application and resource usage in the nodes, and calculate correlation values of resource usage for the application and the sub-application; c) use a time series model to predict the application's workload at a future time point (T+1) based on the current time point (T) and the past time points (T−1, T−2, . . . T−n) and identify resources with high correlation values above a specified threshold; and d) develop a predictive model for resource usage which uses past resource usage data and predicted application workload at time point T+1 to estimate resource usage increments for the identified resource from step c. Specifically speaking, the correlation values are calculated by measuring similarity using collected resource usage and application workloads, if the similarity value is negative, consider its absolute value, wherein the similarity value is derived from cosine calculations using vectors composed of changes in resource usage and application workloads over three consecutive time points.

In addition to the aforementioned cooling resources, it should be noted that the term “cooling resources” used throughout the specification is not limited to physical devices or systems (e.g., air conditioners, fans, and liquid cooling systems). It also encompasses cooling infrastructure, which includes the entire system and setup used for cooling, encompassing all physical devices, systems, and supportive infrastructure (such as ductwork, pumps, and control systems). In the present embodiment, HVAC (Heating, Ventilation, and Air Conditioning) systems and CoolIT advanced liquid cooling solutions are used. HVAC systems, with their comprehensive approach to heating, ventilation, and air conditioning, provide robust climate control capabilities that are essential for maintaining optimal temperature and humidity levels in data centers. This usage ensures the reliable operation of servers and other critical hardware, preventing overheating and reducing energy consumption through efficient climate management.

Moreover, the use of CoolIT's advanced liquid cooling solutions offers significant enhancements in thermal management. CoolIT's direct liquid cooling technology, which circulates coolant close to heat-generating components such as CPUs and GPUs, provides a more efficient and effective method of heat removal compared to traditional air cooling systems. By managing these cooling solutions, the present invention can achieve superior cooling performance, especially in high-density computing environments, further minimizing energy consumption and operational costs while ensuring optimal cooling efficiency.

To provide a comprehensive understanding of the present invention, the following Python integration code segments demonstrate interfacing with HVAC API and CoolIT API, respectively.

Python Integration with HVAC API:
import hvac_api
def adjust_hvac_cooling(temp_setpoint, humidity_setpoint):
   hvac_system=hvac_api.HVACSystem( )
   hvac_system.set_temperature(temp_setpoint)
   hvac_system.set_humidity(humidity_setpoint)
   response=hvac_system.apply_settings( )
   return response
current_temp=get_current_temperature( )
current_humidity=get_current_humidity( )

Below is to obtain the optimal setpoints:
optimal_temp_setpoint=federator_ai.get_optimal_temperature( )
optimal_humidity_setpoint=federator_ai.get_optimal_humidity( )
adjust_response=adjust_hvac_cooling(optimal_temp_setpoint, optimal
_humidity_setpoint)
print(adjust_response)
   Python Integration with CoolIT API:
import coolit_api
def adjust_coolit_flowrate(flowrate):
   coolit_system=coolit_api.CoolITSystem( )
   coolit_system.set_flowrate(flowrate)
   response=coolit_system.apply_settings( )
   return response
current_flowrate=get_current_flowrate( )

Below is to obtain the optimal flowrate:
optimal_flowrate=federator_ai.get_optimal_flowrate( )
adjust_response=adjust_coolit_flowrate(optimal_flowrate)
print(adjust_response)

The above two examples illustrate how the present invention interacts with HVAC and CoolIT systems to dynamically adjust cooling parameters based on real-time data and predictive analytics. This integration ensures that the data center maintains optimal operating conditions while maximizing energy efficiency.

The present invention combines real-time data collection, machine learning-based workload prediction, and advanced cooling control mechanisms to revolutionize energy efficiency and operational cost reduction in data centers. Unlike traditional reactive systems, our approach proactively forecasts workload demands and utilizes virtualization to dynamically allocate resources based on workload dynamics. This proactive strategy enables precise adjustments to fan speeds and cooling liquid movements, ensuring efficient maintenance of necessary cooling and air conditioning levels throughout the data center.

Our system employs multi-layer correlation and causal analysis technologies to deliver real-time insights for just-in-time cooling and air conditioning adjustments, optimizing energy usage without compromising operational integrity. By focusing on specific areas of the data center and leveraging predictive analytics, our approach maximizes energy efficiency and sustainability while seamlessly integrating with existing data center management systems.

In modern GPU-based data centers, where electricity consumption is divided between cooling and air conditioning and operating equipment and servers, optimizing cooling strategies is paramount. Cooling and air conditioning typically account for 30-40% of total electricity consumption, highlighting the critical need for advanced cooling techniques to manage heat generated by high-performance GPU servers. The operation of equipment and servers, especially GPU-based ones like NVIDIA H100 and H200, consumes 50-70% of total electricity, emphasizing the significant impact of optimizing cooling strategies on overall energy efficiency.

The present invention focuses on leveraging workload prediction and cascade causal analysis to dynamically adjust cooling and air conditioning systems for servers and racks. By automatically optimizing cooling based on real-time workload insights, our system can achieve up to 30% energy savings, resulting in substantial cost reductions and a reduced carbon footprint. This proactive approach not only enhances operational efficiency but also aligns with global efforts to mitigate the escalating energy demands of data centers, AI technologies, and the cryptocurrency sector, thereby promoting sustainable growth in the digital infrastructure landscape.

It is to be understood that the specific order or hierarchy of steps in the methods disclosed is an illustration of exemplary processes and may be rearranged based upon design preferences. The accompanying method claims present elements of the various steps in a sample order, and are not meant to be limited to the specific order or hierarchy presented unless specifically recited therein.

Although embodiments have been described herein with respect to particular configurations and sequences of operations, it should be understood that alternative embodiments may add, omit, or change elements, operations and the like. Accordingly, the embodiments disclosed herein are meant to be examples and not limitations.

What is claimed is:

1. A method for optimizing cooling resources in a data center based on workload prediction, comprising the steps of:
continuously collecting data in real-time from a plurality of sensors distributed across various sections of the data center;
predicting future workload demands and corresponding cooling requirements over time and space in each section of the data center using historical and real-time collected data;
determining whether to allocate the predicted workload demand to a section that meets the corresponding cooling requirements or to adjust the cooling resources to achieve the required cooling levels, whichever results in more optimized energy usage; and
dynamically adjusting the cooling resources in each section of the data center based on real-time and predicted workload demands over time to minimize energy consumption and operational costs, thereby ensuring optimal cooling without over-provisioning.

2. The method according to claim 1, wherein the data collected from the plurality of sensors include: temperatures, workload demands, humidity, environmental metrics, and system performance.

3. The method according to claim 1, wherein the future workload demands are predicted by performing multi-layer correlation and causal analysis.

4. The method according to claim 1, wherein the cooling resources are adjusted to reduce cooling in sections not operating at full capacity and to enhance cooling in sections predicted to generate heat due to increased workload demands.

5. The method according to claim 1, wherein the cooling resources are adjusted by adjusting cooling parameters of the cooling resources, including fan speeds, liquid cooling rates, and air-conditioning settings.

6. The method according to claim 1, wherein each section of the data center includes at least one rack of servers, each with its own set of cooling resources.

7. The method according to claim 1, wherein the cooling resources comprises air cooling system, liquid cooling system, evaporative cooling system, hybrid cooling system, and free cooling system.

8. The method according to claim 1, further comprising a step of: allocating the predicted workload demand to a section that meets the corresponding cooling requirements, if it results in more optimized energy usage compared to adjusting the cooling resources to achieve the required cooling levels.

9. The method according to claim 1, further comprising a step of: building and refining a prediction model for predicting future workload demands and corresponding cooling requirements, and a correlation model between the workload demands and the cooling resources using machine learning.

10. The method according to claim 1, further comprising a step of: hibernating unused or underutilized servers in the data center and adjusting cooling resources to reduce cooling in sections containing these servers.

11. A system for optimizing cooling resources in a data center based on workload prediction, comprising:
a plurality of sensors, distributed across various sections of the data center;
a data collecting module, connected to the plurality of sensors, for continuously collecting data in real-time from the plurality of sensors;
a prediction module, connected to the data collecting module, for predicting future workload demands and corresponding cooling requirements over time and space in each section of the data center using historical and real-time collected data;
a processing module, connected to the prediction module, for determining whether to allocate the predicted workload demand to a section that meets the corresponding cooling requirements or to adjust the cooling resources to achieve the required cooling levels, whichever results in more optimized energy usage; and
a dynamic adjustment module, connected to the processing module, for dynamically adjusting the cooling resources in each section of the data center based on real-time and predicted workload demands over time to minimize energy consumption and operational costs, thereby ensuring optimal cooling without over-provisioning.

12. The system according to claim 11, wherein the data collected by the data collecting module from the plurality of sensors include: temperatures, workload demands, humidity, environmental metrics, and system performance.

13. The system according to claim 11, wherein the prediction module predicts the future workload demands by performing multi-layer correlation and causal analysis.

14. The system according to claim 11, wherein the cooling resources are adjusted to reduce cooling in sections not operating at full capacity and to enhance cooling in sections predicted to generate heat due to increased workload demands.

15. The system according to claim 11, wherein the cooling resources are adjusted by adjusting cooling parameters of the cooling resources, including fan speeds, liquid cooling rates, and air-conditioning settings.

16. The system according to claim 11, wherein each section of the data center includes at least one rack of servers, each with its own set of cooling resources.

17. The system according to claim 11, wherein the cooling resources comprises air cooling system, liquid cooling system, evaporative cooling system, hybrid cooling system, and free cooling system.

18. The system according to claim 11, wherein the processing module allocates the predicted workload demand to a section that meets the corresponding cooling requirements, if it results in more optimized energy usage compared to adjusting the cooling resources to achieve the required cooling levels.

19. The system according to claim 11, wherein the prediction module comprises a prediction model for predicting future workload demands and corresponding cooling requirements; and a correlation model for calculating correlations between the workload demands and the cooling resources, both using machine learning techniques that are dynamically refined over time.

20. The system according to claim 11, wherein the processing module sets unused or underutilized servers in the data center to hibernating mode; and the dynamic adjustment module reduces cooling in sections containing these hibernating servers.
